(19) United States
(12) Patent Application Publication
(10) Pub. No.: US 2026/0271806 A1
(43) Pub. Date: Sep. 10, 2026

(54) SEMICONDUCTOR DEVICE

(71) Applicant: ROHM CO., LTD., Kyoto-shi (JP)

(72) Inventors: Tomohiko HARA, Kyoto-shi (JP); Kensuke MIKADO, Kyoto-shi (JP)

(21) Appl. No.: 19/665,658

(22) Filed: May 1, 2026

Related U.S. Application Data
(63) Continuation of application No. PCT/JP2024/038866, filed on Oct. 31, 2024.

(30) Foreign Application Priority Data
Nov. 9, 2023 (JP) 2023-191321

(51) Int. Cl. H10W 90/00; H10W 74/10

(52) U.S. Cl. CPC H10W 90/811; H10W 74/111; H10W 90/756

(57) ABSTRACT

A semiconductor device includes: a first lead including a first pad portion; a first semiconductor element disposed on a first side in a thickness direction relative to the first pad portion; a second lead including a second pad portion spaced apart from the first pad portion toward a first side in a first direction; a second semiconductor element disposed on the first side in the thickness direction relative to the second pad portion; a first bonding wire bonded to the first semiconductor element; a second bonding wire bonded to the second semiconductor element; and a sealing resin. As viewed in the first direction, the first semiconductor element overlaps with the second semiconductor element. The first semiconductor element is offset toward one side in the second direction, and the second semiconductor element is offset toward the one side in the second direction.

### TECHNICAL FIELD

The present disclosure relates to semiconductor devices.

### BACKGROUND ART

Various configurations have been proposed for semiconductor devices incorporating semiconductor elements. JP-A-2019-121745 discloses an example of a conventional semiconductor device. The semiconductor device disclosed in the document includes a plurality of leads, a semiconductor element, a plurality of wires, and a sealing resin. The semiconductor element is mounted on the die pad of the leads. The wires are electrically bonded to the semiconductor element and to the lead. The sealing resin covers the semiconductor element, the wires, and portions of the leads. The sealing resin is formed by injecting molten resin into the mold cavity and then solidifying the resin. In some configurations, a plurality of semiconductor elements are disposed on the leads. Depending on their arrangement, the flow of resin around the semiconductor elements may be adversely affected. Reduced flowability of resin may result in poor adhesion between the leads and the resin, which may lead to internal delamination of the sealing resin.

### BRIEF DESCRIPTION OF THE DRAWINGS

FIG. 1 is a perspective view showing a semiconductor device according to a first embodiment of the present disclosure.

FIG. 2 is a perspective view showing the semiconductor device according to the first embodiment of the present disclosure.

FIG. 3 is a perspective view showing a main portion of the semiconductor device according to the first embodiment of the present disclosure.

FIG. 4 is a perspective view showing a main portion of the semiconductor device according to the first embodiment of the present disclosure.

FIG. 5 is a plan view showing the semiconductor device according to the first embodiment of the present disclosure.

FIG. 6 is a bottom view showing the semiconductor device according to the first embodiment of the present disclosure.

FIG. 7 is a front view showing the semiconductor device according to the first embodiment of the present disclosure.

FIG. 8 is a side view showing the semiconductor device according to the first embodiment of the present disclosure.

FIG. 9 is a plan view showing a main portion of the semiconductor device according to the first embodiment of the present disclosure.

FIG. 10 is a bottom view showing a main portion of the semiconductor device according to the first embodiment of the present disclosure.

FIG. 11 is a sectional view taken along line XI-XI in FIG. 10.

FIG. 12 is a sectional view taken along line XII-XII in FIG. 10.

FIG. 13 is a sectional view taken along line XIII-XIII in FIG. 10.

FIG. 14 is a bottom view showing a main portion of a semiconductor device according to a first variation of the first embodiment of the present disclosure.

FIG. 15 is a bottom view showing a main portion of a semiconductor device according to a second variation of the first embodiment of the present disclosure.

FIG. 16 is a bottom view showing a main portion of a semiconductor device according to a third variation of the first embodiment of the present disclosure.

FIG. 17 is a bottom view showing a main portion of a semiconductor device according to a second embodiment of the present disclosure.

FIG. 18 is a sectional view taken along line XVIII-XVIII in FIG. 17.

FIG. 19 is a bottom view showing a main portion of a semiconductor device according to a first variation of the second embodiment of the present disclosure.

FIG. 20 is a bottom view showing a main portion of a semiconductor device according to a second variation of the second embodiment of the present disclosure.

FIG. 21 is a bottom view showing a main portion of a semiconductor device according to a third variation of the second embodiment of the present disclosure.

### DETAILED DESCRIPTION

The following specifically describes preferred embodiments of the present disclosure with reference to the drawings.

In the present disclosure, the terms such as “first”, “second”, “third”, and so on are used only as labels and are not intended to imply any order of the items to which they refer.

In the present disclosure, the expressions “An object A is formed in an object B”, and “An object A is formed on an object B” imply the situations where, unless otherwise specifically noted, “the object A is formed directly in or on the object B”, and “the object A is formed in or on the object B, with something else interposed between the object A and the object B.” Likewise, the expressions “An object A is arranged in an object B”, and “An object A is arranged on an object B” imply the situations where, unless otherwise specifically noted, “the object A is arranged directly in or on the object B”, and “the object A is arranged in or on the object B, with something else interposed between the object A and the object B”. Likewise, the expression “An object A is positioned on an object B” implies the situations where, unless otherwise specifically noted, “the object A is positioned on the object B, in contact with the object B”, and “the object A is positioned on the object B, with something else interposed between the object A and the object B.” The expression “An object A overlaps with an object B as viewed in a certain direction” implies the situations where, unless otherwise specifically noted, “the object A overlaps with the entirety of the object B”, and “the object A overlaps with a portion of the object B.” In the present disclosure, the expression “A surface A faces a direction B (one side or the other side in that direction) is not limited to the situation where the surface A forms an angle of 90° with the direction B, but includes the situation where the surface A is inclined relative to the direction B.

### First Embodiment

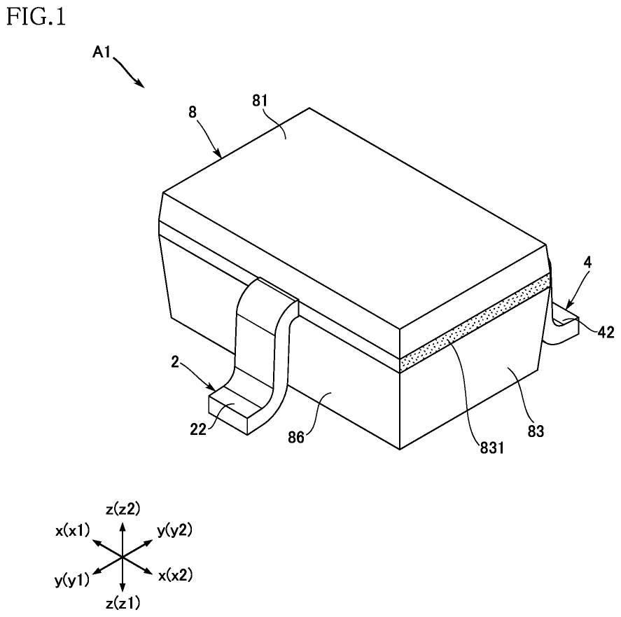

FIGS. 1 to 13 show a semiconductor device according to a first embodiment of the present disclosure. The semiconductor device A1 of the present embodiment includes a first semiconductor element 11, a second semiconductor element 12, a first lead 2, a second lead 3, a third lead 4, a first bonding wire 5, a second bonding wire 6, and a sealing resin 8. The semiconductor device A1 additionally includes a conductive bonding layer 19.

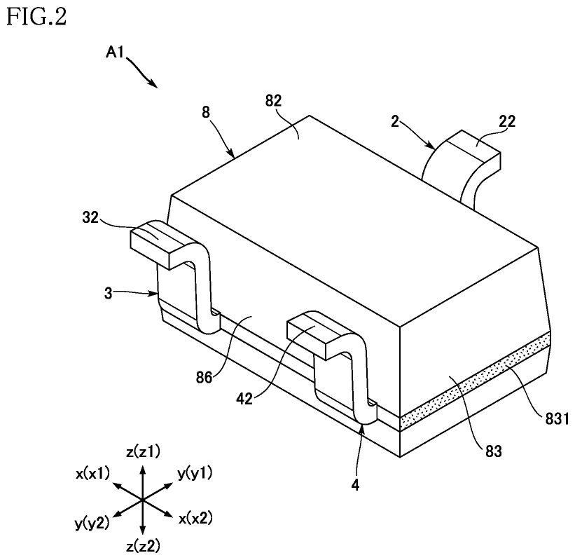

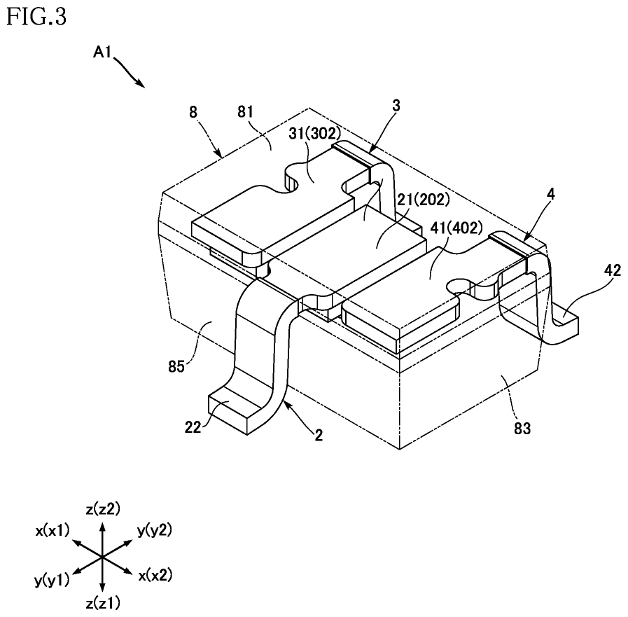

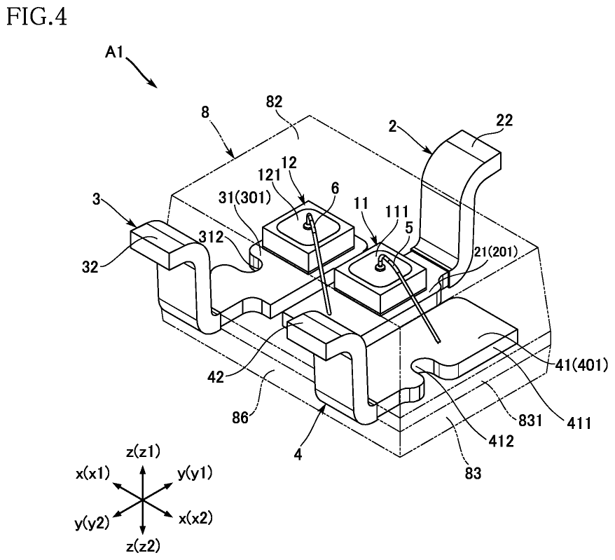

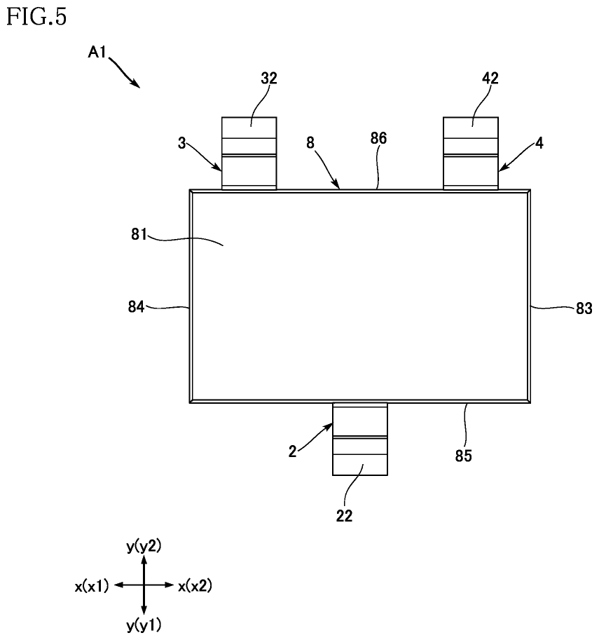

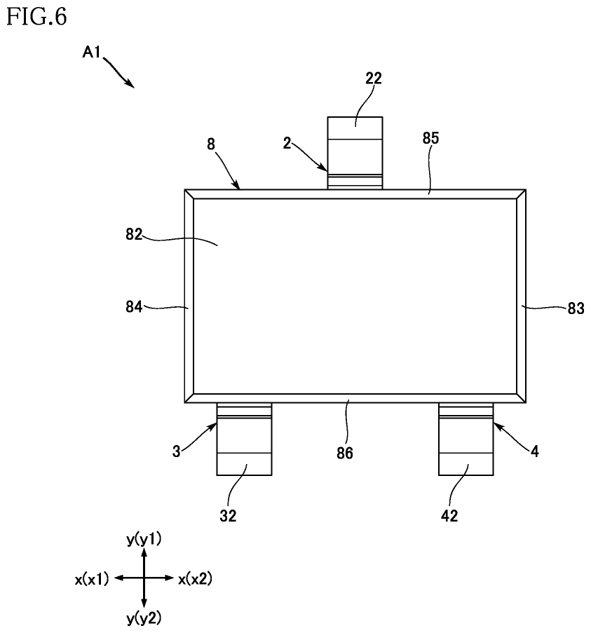

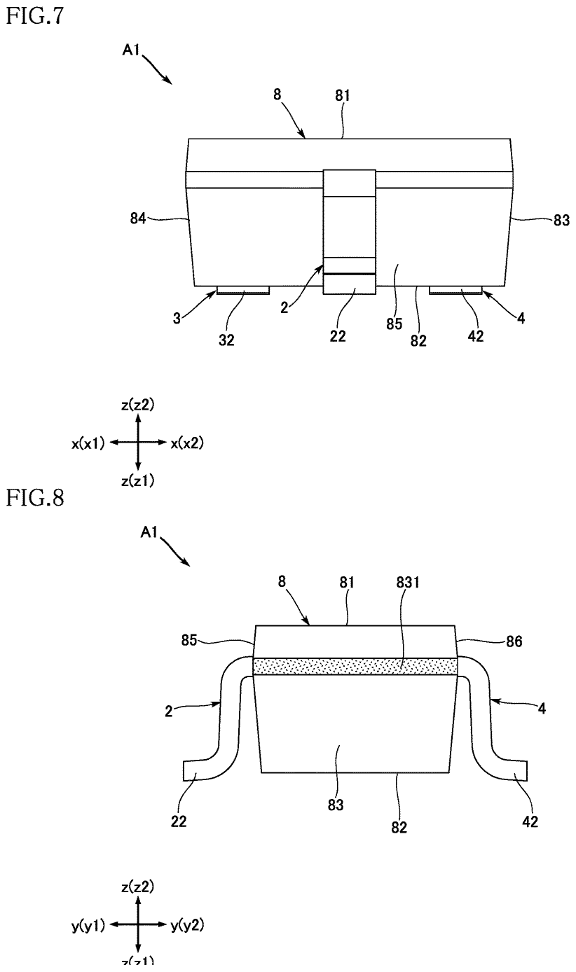

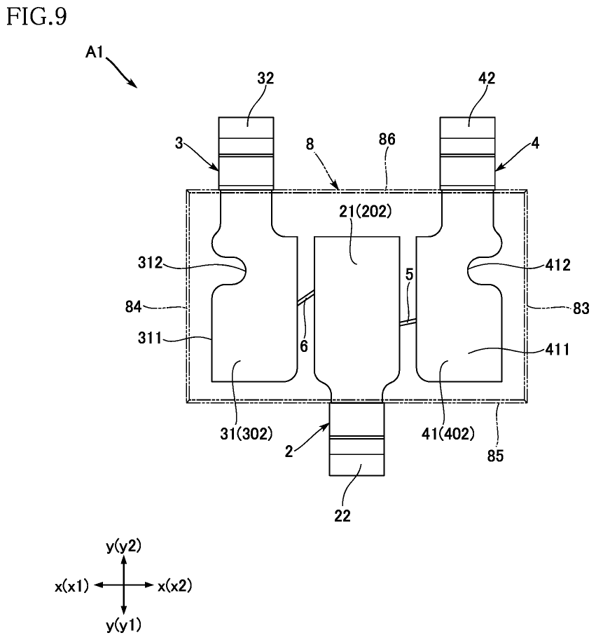

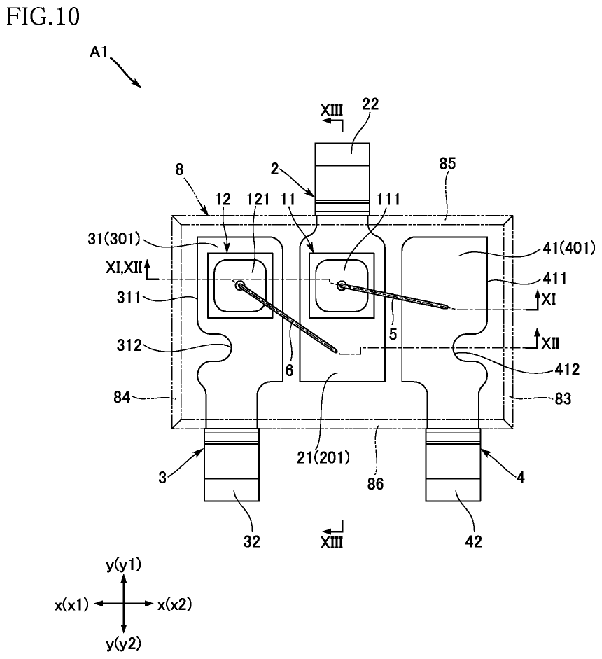

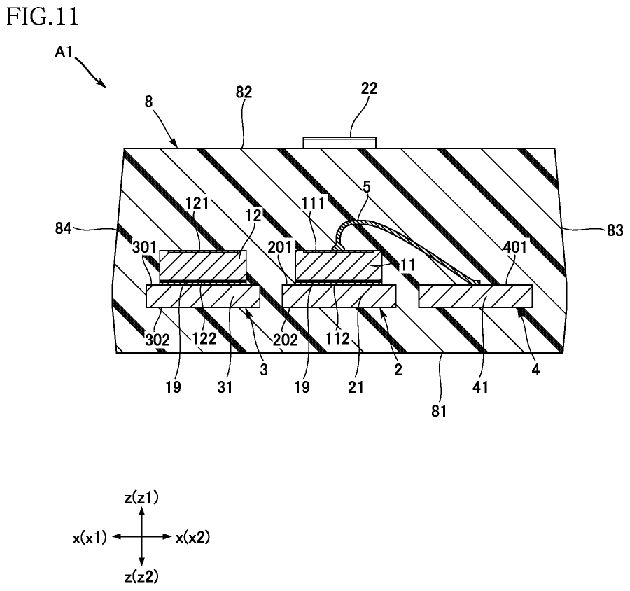

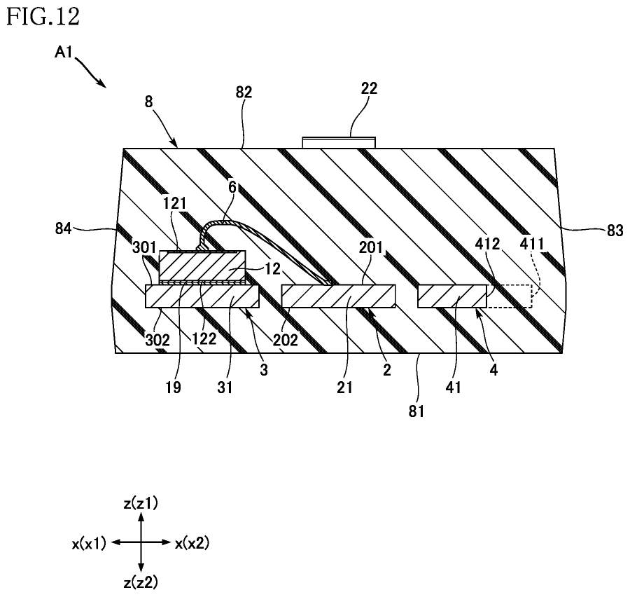

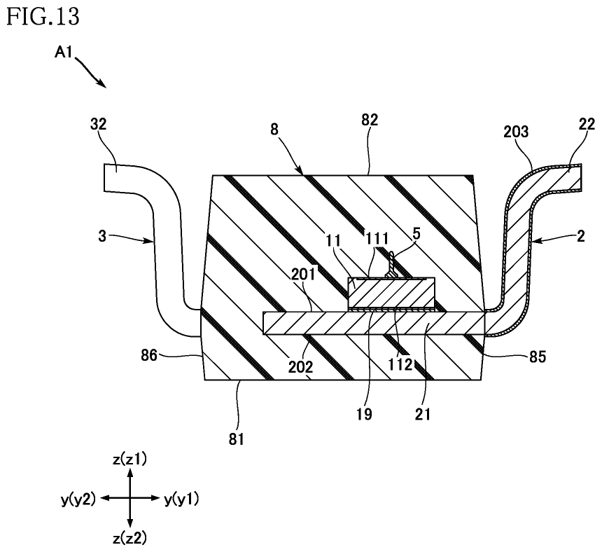

FIGS. 1 and 2 are perspective views showing the semiconductor device A1. FIGS. 3 and 4 are perspective views each showing a main portion of the semiconductor device A1. In FIGS. 3 and 4, the outline of the sealing resin 8 is indicated by an imaginary line (dash-dot-dot line). FIG. 5 is a plan view showing the semiconductor device A1. FIG. 6 is a bottom view showing the semiconductor device A1. FIG. 7 is a front view showing the semiconductor device A1. FIG. 8 is a side view showing the semiconductor device A1. FIG. 9 is a plan view showing a main portion of the semiconductor device A1. FIG. 10 is a bottom view showing a main portion of the semiconductor device A1. In FIGS. 9 and 10, the outline of the sealing resin 8 is indicated by an imaginary line (dash-dot-dot line). FIG. 11 is a sectional view taken along line XI-XI in FIG. 10. FIG. 12 is a sectional view taken along line XII-XII in FIG. 10. FIG. 13 is a sectional view taken along line XIII-XIII in FIG. 10.

In these figures, the thickness direction of the present disclosure is referred to a “thickness direction z.” A direction perpendicular to the thickness direction z is referred to as a “first direction x”. The direction perpendicular to both the thickness direction z and the first direction x is referred to as a “second direction y.” Further, one side along the thickness direction z corresponds to the “first side in the thickness direction” of the present disclosure, and is referred to as a “z1 side in the thickness direction z”. The other side along the thickness direction z corresponds to the “second side in the thickness direction” of the present disclosure, and is referred to as a “z2 side in the thickness direction z”. One side along the first direction x corresponds to the “first side in the first direction” of the present disclosure, and is referred to as a “x1 side in the first direction x”. The other side along the first direction x corresponds to the “second side in the first direction” of the present disclosure, and is referred to as a “x2 side in the first direction x”. One side along the second direction y corresponds to the “first side in the second direction” of the present disclosure, and is referred to as a “y1 side in the second direction y”. The other side along the second direction y corresponds to the “second side in the second direction” of the present disclosure, and is referred to as a “y2 side in the second direction y”.

The first semiconductor element 11 and the second semiconductor element 12 are components that perform an electrical function of the semiconductor device A1. The first semiconductor element 11 and the second semiconductor element 12 are not limited to a particular type. In the present embodiment, the first semiconductor element 11 and the second semiconductor element 12 are diodes. In the present embodiment, each of the first semiconductor element 11 and the second semiconductor element 12 is rectangular as viewed in the thickness direction z.

As shown in FIGS. 4, 10, 11, and 13, the first semiconductor element 11 includes an obverse-surface electrode 111 and a reverse-surface electrode 112. The obverse-surface electrode 111 is disposed on a surface of the first semiconductor element 11 facing the z1 side in the thickness direction z. The reverse-surface electrode 112 is disposed on a surface of the first semiconductor element 11 facing the z2 side in the thickness direction z. For example, the obverse-surface electrode 111 is an anode, and the reverse-surface electrode 112 is a cathode.

As shown in FIGS. 4 and 10 to 12, the second semiconductor element 12 includes an obverse-surface electrode 121 and a reverse-surface electrode 122. The obverse-surface electrode 121 is disposed on a surface of the second semiconductor element 12 facing the z1 side in the thickness direction z. The reverse-surface electrode 122 is disposed on a surface of the second semiconductor element 12 facing the z2 side in the thickness direction z. For example, the obverse-surface electrode 121 is an anode, and the reverse-surface electrode 122 is a cathode.

The first lead 2, the second lead 3, and the third lead 4 are formed from a metal plate (lead frame) by punching, bending, or other processing. For example, the first lead 2, the second lead 3, and the third lead 4 each contain copper (Cu) or Ni (nickel). In the present embodiment, the first lead 2, the second lead 3, and the third lead 4 are each made of a material containing Fe (iron) and Ni (nickel), such as a 42 alloy.

As shown in FIGS. 1 to 13, the first lead 2 includes a first pad portion 21 and a terminal portion 22.

The first pad portion 21 is a portion on which the first semiconductor element 11 is mounted. The first pad portion 21 includes a first obverse surface 201 and a first reverse surface 202. The first obverse surface 201 faces the z1 side in the thickness direction z. The first reverse surface 202 faces the z2 side in the thickness direction z. The second bonding wire 6 is connected to the first obverse surface 201 of the first pad portion 21. The first obverse surface 201 may be covered with, for example, a silver (Ag) plating layer. The first pad portion 21 is generally rectangular and elongated in the second direction y.

As shown in FIGS. 4, 10, 11, and 13, the first semiconductor element 11 is bonded to the first obverse surface 201 of the first pad portion 21 via a conductive bonding layer 19. In the present embodiment, the conductive bonding layer 19 is made of a conductive material. The reverse-surface electrode 112 of the first semiconductor element 11 faces the first obverse surface 201. The reverse-surface electrode 112 and the first obverse surface 201 are electrically bonded via the conductive bonding layer 19. The first semiconductor element 11 is die-bonded to the first obverse surface 201 of the first pad portion 21. The composition of the conductive bonding layer 19 is not particularly limited, and may be formed by sintering a paste containing metals, such as silver. Alternatively, the conductive bonding layer 19 may be formed from an Au—Si eutectic alloy or solder (metal containing tin and silver), instead of by sintering a metal paste. The composition of other conductive bonding layers 19, such as those for bonding the second semiconductor element 12, is similar to that of the conductive bonding layer 19 described above.

As shown in FIGS. 4, 10, and 13, the first semiconductor element 11 on the first pad portion 21 is offset toward one side in the second direction y. In the present embodiment, the first semiconductor element 11 on the first pad portion 21 is offset toward the y1 side in the second direction y.

The first terminal portion 22 is connected to the first pad portion 21 on the y1 side in the second direction y. The first terminal portion 22 extends in the second direction y as viewed in the thickness direction z. As shown in FIGS. 1 to 13, the first terminal portion 22 is exposed from the sealing resin 8 and includes a portion protruding from the sealing resin 8 toward the y1 side in the second direction y, a portion bent toward the z1 side in the thickness direction z, and a portion positioned on the z1 side in the thickness direction z. The first terminal portion 22 serves as a terminal used to mount the semiconductor device A1. The first terminal portion 22 is electrically connected to the reverse-surface electrode 112 of the first semiconductor element 11.

The portion of the first lead 2 that is exposed from the sealing resin 8 (the first terminal portion 22) may be covered with a plating layer of, for example, a Sn (tin)-based alloy. In the illustrated example, the first terminal portion 22 is covered with a plating layer 203.

The second lead 3 is positioned on the x1 side in the first direction x relative the first lead 2. As shown in FIGS. 2 to 7 and 9 to 13, the second lead 3 includes a second pad portion 31 and a second terminal portion 32.

The second pad portion 31 is located at a position spaced from and adjacent to the first pad portion 21 on the x1 side in the first direction x. The second pad portion 31 is a portion on which the second semiconductor element 12 is mounted. The second pad portion 31 includes a second obverse surface 301 and a second reverse surface 302. The second obverse surface 301 faces the z1 side in the thickness direction z. The second reverse surface 302 faces the z2 side in the thickness direction z. The second obverse surface 301 may be covered with, for example, a silver (Ag) plating layer. The second pad portion 31 is generally rectangular and elongated in the second direction y.

As shown in FIGS. 4, 9, and 10, the second pad portion 31 includes a recess 312 The recess 312 is recessed inward from an edge 311, which is an edge of the second pad portion 31 in the first direction x. In the illustrated example, the recess 312 is recessed from the edge 311 on the x1 side in the first direction x of the second pad portion 31 toward the x2 side in the first direction x. In the second direction y, the recess 312 in the second pad portion 31 is offset toward the y2 side.

As shown in FIGS. 4 and 10 to 12, the second semiconductor element 12 is bonded to the second obverse surface 301 of the second pad portion 31 via a conductive bonding layer 19. In the present embodiment, the conductive bonding layer 19 is made of a conductive material. The reverse-surface electrode 122 of the second semiconductor element 12 faces the second obverse surface 301. The reverse-surface electrode 122 and the second obverse surface 301 are electrically bonded via the conductive bonding layer 19. The second semiconductor element 12 is die-bonded to the second obverse surface 301 of the second pad portion 31.

As shown in FIGS. 4 and 10, the second semiconductor element 12 on the second pad portion 31 is offset toward one side in the second direction y. The second semiconductor element 12 is offset toward the same side in the second direction y as the first semiconductor element 11. In the present embodiment, the second semiconductor element 12 on the second pad portion 31 is offset toward the y1 side in the second direction y. Further, the second semiconductor element 12 is spaced apart from the recess 312 described above.

As viewed in the first direction x, the second semiconductor element 12 overlaps with the first semiconductor element 11. In the illustrated example, the first semiconductor element 11 and the second semiconductor element 12 are of the same size. As viewed in the first direction x, the second semiconductor element 12 overlaps with the entirety of the first semiconductor element 11.

The second terminal portion 32 is connected to the second pad portion 31 on the y2 side in the second direction y. The second terminal portion 32 extends in the second direction y as viewed in the thickness direction z. As shown in FIGS. 2 to 7, 9, 10, and 13, the second terminal portion 32 is exposed from the sealing resin 8 and includes a portion protruding from the sealing resin 8 toward the y2 side in the second direction y, a portion bent toward the z1 side in the thickness direction z, and a portion positioned on the z1 side in the thickness direction z. The second terminal portion 32 serves as a terminal used to mount the semiconductor device A1. The second terminal portion 32 is electrically connected to the reverse-surface electrode 122 of the second semiconductor element 12.

The portion of the second lead 3 that is exposed from the sealing resin 8 (the second terminal portion 32) may be covered with a plating layer of, for example, a Sn (tin)-based alloy. Although the details are not shown in the figures, the second terminal portion 32 is covered with a plating layer, similar to that of the first terminal portion 22.

The third lead 4 is positioned on the x2 side in the first direction x relative to the first lead 2. As shown in FIGS. 1 to 12, the third lead 4 includes a third pad portion 41 and a third terminal portion 42.

The third pad portion 41 is located at a position spaced from and adjacent to the first pad portion 21 on the x2 side in the first direction x. The third pad portion 41 includes a third obverse surface 401 and a third reverse surface 402. The third obverse surface 401 faces the z1 side in the thickness direction z. The third reverse surface 402 faces the z2 side in the thickness direction z. The first bonding wire 5 is connected to the third obverse surface 401 of the third pad portion 41. For example, the third obverse surface 401 may be covered with a silver (Ag) plating layer. The third pad portion 41 is generally rectangular and elongated in the second direction y.

As shown in FIGS. 4, 9, and 10, the third pad portion 41 includes a recess 412. The recess 412 is recessed inward from an edge 411, which is an edge of the third pad portion 41 in the first direction x. In the illustrated example, the recess 412 is recessed from the edge 411 on the x2 side in the first direction x of the third pad portion 41 toward the x1 side in the first direction x. The recess 412 in the third pad portion 41 is offset toward the y2 side in the second direction y.

The third terminal portion 42 is connected to the third pad portion 41 on the y2 side in the second direction y. The third terminal portion 42 extends in the second direction y as viewed in the thickness direction z. As shown in FIGS. 1 to 10, the third terminal portion 42 is exposed from the sealing resin 8 and includes a portion protruding from the sealing resin 8 toward the y2 side in the second direction y, a portion bent toward the z1 side in the thickness direction z, and a portion positioned on the z1 side in the thickness direction z. As viewed in the first direction x, the third terminal portion 42 is shaped and sized to substantially overlap with the second terminal portion 32. The third terminal portion 42 serves as a terminal used to mount the semiconductor device A1.

The portion of the third lead 4 that is exposed from the sealing resin 8 (the third terminal portion 42) may be covered with a plating layer of, for example, a Sn (tin)-based alloy. Although the details are not shown in the figures, the third terminal portion 42 is covered with a plating layer, similar to that of the first terminal portion 22.

The first bonding wire 5 is bonded to the obverse-surface electrode 111 of the fi semiconductor element 11 and to the third pad portion 41 of the third lead 4. The material of the first bonding wire 5 is not particularly limited, and examples include metals, such as aluminum (Al), copper (Cu), and Au (gold). The number of the first bonding wires 5 is not limited either, and a plurality of first bonding wires 5 may be included. In the illustrated example, the first bonding wire 5 contains Au (gold). The third terminal portion 42 of the third lead 4 is electrically connected to the obverse-surface electrode 111 of the first semiconductor element 11 via the first bonding wire 5.

The second bonding wire 6 is bonded to the obverse-surface electrode 121 of the second semiconductor element 12 and to the first pad portion 21 of the first lead 2. The material of the second bonding wire 6 is not particularly limited, and examples include metals, such as aluminum (Al), copper (Cu), and Au (gold). In the illustrated example, the second bonding wire 6 contains Au (gold). The position on the first pad portion 21 where the second bonding wire 6 is bonded is located on the y2 side in the second direction y relative to the first semiconductor element 11. The first terminal portion 22 of the first lead 2 is electrically connected to the obverse-surface electrode 121 of the second semiconductor element 12 via the second bonding wire 6.

As shown in FIGS. 1 to 13, the sealing resin 8 covers the first semiconductor element 11, the second semiconductor element 12, the first bonding wire 5, and the second bonding wire 6, and a portion of each of the first lead 2, the second lead 3, and the third lead 4. Specifically, the sealing resin 8 covers the first pad portion 21, the second pad portion 31, and the third pad portion 41 of the first lead 2, the second lead 3, and the third lead 4, respectively. The sealing resin 8 is electrically insulative. In one example, the sealing resin 8 is made of a material containing a black epoxy resin. The shape of the sealing resin 8 is not particularly limited. As shown in FIGS. 1 to 13, the sealing resin 8 of the present embodiment includes a resin obverse surface 81, a resin reverse surface 82, a first resin side surface 83, a second resin side surface 84, a third resin side surface 85, and a fourth resin side surface 86.

The resin obverse surface 81 faces the z2 side in the thickness direction z. The resin reverse surface 82 faces the z1 side in the thickness direction z. In the illustrated example, the resin obverse surface 81 and the resin reverse surface 82 are flat, but this is not limiting. In other examples, the resin obverse surface 81 and the resin reverse surface 82 may be curved or may have a bend.

The first resin side surface 83 faces the x2 side in the first direction x. The second resin side surface 84 faces the x1 side in the first direction x. In the illustrated example, the first resin side surface 83 and the second resin side surface 84 each have a slight bend, but this is not limiting. In other examples, the first resin side surface 83 and the second resin side surface 84 may be curved or flat.

In the present embodiment, the first resin side surface 83 includes a resin injection mark 831 as shown in FIGS. 1, 2, and 8. The resin injection mark 831 has a rougher surface than other regions of the first resin side surface 83. The resin injection mark 831 appears when the sealing resin 8 is cut near the resin injection gate during the process of forming the sealing resin 8 in the manufacture of the semiconductor device A1. During the process of forming the sealing resin 8, molten resin is injected through the resin injection gate into the mold cavity and flows in the first direction x toward the x1 side to fill the cavity. In the semiconductor device A1, the resin injection mark 831 extends in the second direction y and has an elongated rectangular shape. The resin injection mark 831 is offset in the thickness direction z toward the z2 side of the thickness direction z. In the thickness direction z, the resin injection mark 831 is at the same position as the first pad portion 21, the second pad portion 31, and the third pad portion 41.

The third resin side surface 85 faces the y1 side in the second direction y. The fourth resin side surface 86 faces the y2 side in the second direction y. In the illustrated example, the third resin side surface 85 and the fourth resin side surface 86 have a slight bend, but this is not limiting. In other examples, the third resin side surface 85 and the fourth resin side surface 86 may be curved or flat. In the present embodiment, the first terminal portion 22 protrudes from the third resin side surface 85, and the second terminal portion 32 and the third terminal portion 42 protrude from the fourth resin side surface 86.

The following describes the operation of the semiconductor device A1.

In the present embodiment, the first semiconductor element 11 and the second semiconductor element 12, which are respectively mounted on the first pad portion 21 and the second pad portion 31 positioned next to each other in the first direction x, overlap with each other as viewed in the first direction x. The first semiconductor element 11 on the first pad portion 21 is offset toward the y1 side in the second direction y (one side in the second direction y). The second semiconductor element 12 on the second pad portion 31 is offset toward the y1 side in the second direction y (the same side in the second direction y as the first semiconductor element 11). By offsetting the first semiconductor element 11 and the second semiconductor element 12 toward the same side in the second direction y, the flowability of molten resin improves during the process of forming the sealing resin 8. Specifically, the molten resin flows more easily from the x2 side toward the x1 side in the first direction x around the first semiconductor element 11 and the second semiconductor element 12. Consequently, adhesion between the sealing resin 8 and each of the first pad portion 21 (the first lead 2) and the second pad portion 31 (the second lead 3) is improved, so that internal delamination of the sealing resin 8 is prevented.

In the semiconductor device A1, the second semiconductor element 12 overlaps with the entirety of the first semiconductor element 11 as viewed in the first direction x. With this configuration, the flowability of molten resin is improved during the formation of the sealing resin 8. Specifically, the molten resin flows more easily from the x2 side toward the x1 side in the first direction x around the first semiconductor element 11 and the second semiconductor element 12. Consequently, adhesion between the sealing resin 8 and each of the first pad portion 21 and the second pad portion 31 is improved, so that internal delamination of the sealing resin 8 is prevented more reliably.

The second semiconductor element 12 is mounted on the second pad portion 31 that includes a recess 312. The recess 312 is recessed inward from the edge 311, which is an edge of the second pad portion 31 in the first direction x. This serves to improve adhesion between the sealing resin 8 and the second pad portion 31 (the second lead 3). This is desirable for preventing internal delamination of the sealing resin 8.

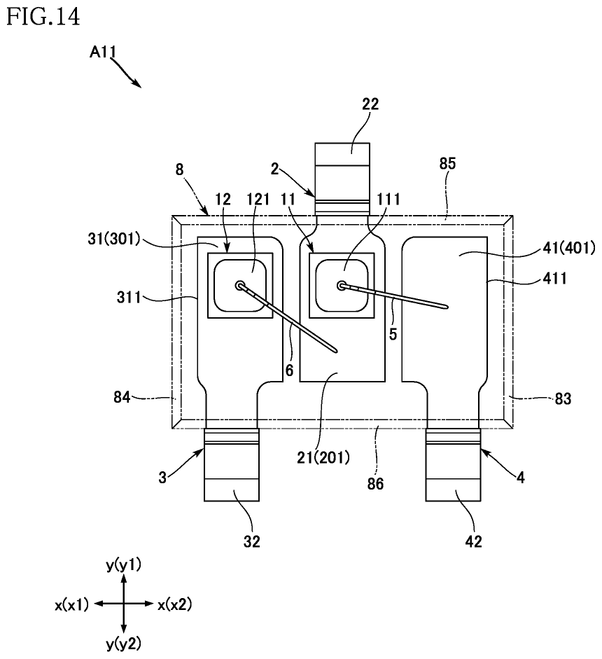

FIGS. 14 to 21 show variations and other embodiments of the semiconductor device according to the present disclosure. In these figures, elements that are identical or similar to those described in the above embodiment are indicated by the same reference numerals, and redundant descriptions are omitted. The configurations of the elements and components in each embodiment and each variation may be appropriately combined with one another to the extent that no technical inconsistencies arise.

### First Variation of First Embodiment

FIG. 14 shows a first variation of the semiconductor device A1. FIG. 14 is a bottom view showing a main portion of the semiconductor device A11 according to the first variation. In FIG. 14, the outline of the sealing resin 8 is indicated by an imaginary line (dash-dot-dot line). In the semiconductor device A11, the shapes of the second pad portion 31 and the third pad portion 41 differ from those in the semiconductor device A1.

In the semiconductor device A11, the second pad portion 31 does not include a recess 312, and the third pad portion 41 does not include a recess 412. The position of the first semiconductor element 11 on the first pad portion 21 and the position of the second semiconductor element 12 on the second pad portion 31 are the same as those in the semiconductor device A1.

In the semiconductor device A11, the first semiconductor element 11 and the second semiconductor element 12, which are respectively mounted on the first pad portion 21 and the second pad portion 31 positioned next to each other in the first direction x, overlap with each other as viewed in the first direction x. The first semiconductor element 11 on the first pad portion 21 is offset toward the y1 side in the second direction y (one side in the second direction y). The second semiconductor element 12 on the second pad portion 31 is offset toward the y1 side in the second direction y (the same side in the second direction y as the first semiconductor element 11). By offsetting the first semiconductor element 11 and the second semiconductor element 12 toward the same side in the second direction y, the flowability of molten resin improves during the process of forming the sealing resin 8. Specifically, the molten resin flows more easily from the x2 side toward the x1 side in the first direction x around the first semiconductor element 11 and the second semiconductor element 12. Consequently, adhesion between the sealing resin 8 and each of the first pad portion 21 (the first lead 2) and the second pad portion 31 (the second lead 3) is improved, so that internal delamination of the sealing resin 8 is prevented. Additionally, the semiconductor device A11 provides the same advantages as the semiconductor device A1, to the extent that they share the same configuration.

### Second Variation of First Embodiment

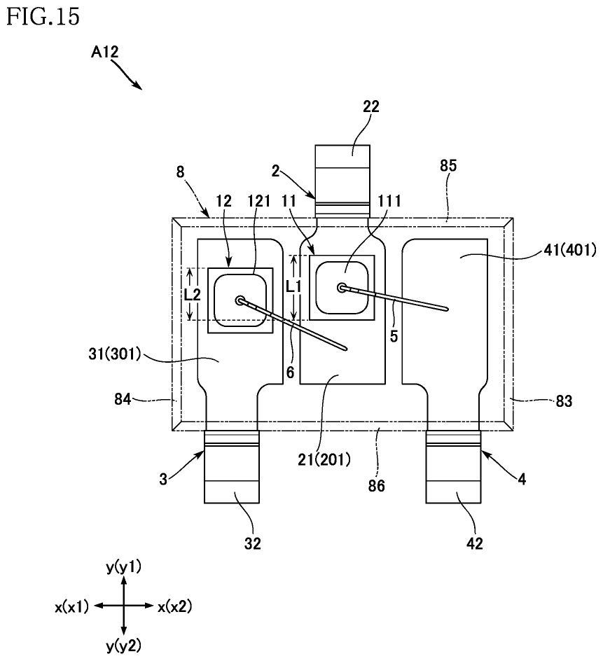

FIG. 15 shows a second variation of the semiconductor device A1. FIG. 15 is a bottom view showing a main portion of the semiconductor device A12 according to the second variation. In FIG. 15, the outline of the sealing resin 8 is indicated by an imaginary line (dash-dot-dot line). In the semiconductor device A12, the position of the second semiconductor element 12 on the second pad portion 31 differs from that in the semiconductor device A11 described above.

In the semiconductor device A12, the second semiconductor element 12 is positioned closer to the y2 side in the second direction y than in the semiconductor device A11. In this variation, as viewed in the first direction x, the second semiconductor element 12 overlaps with only a portion of the first semiconductor element 11, rather than with the entirety of the first semiconductor element 11. When L1 denotes the length of the first semiconductor element 11 in the second direction y, and L2 denotes the length, in the second direction y, of the overlap between the first semiconductor element 11 and the second semiconductor element 12 as viewed in the first direction x, L2 is at least 60% of L1. That is, the second semiconductor element 12 overlaps with most of the first semiconductor element 11 as viewed in the first direction x.

In the semiconductor device A12, the first semiconductor element 11 and the second semiconductor element 12, which are respectively mounted on the first pad portion 21 and the second pad portion 31 positioned next to each other in the first direction x, overlap with each other as viewed in the first direction x. The first semiconductor element 11 on the first pad portion 21 is offset toward the y1 side in the second direction y (one side in the second direction y). The second semiconductor element 12 on the second pad portion 31 is offset toward the y1 side in the second direction y (the same side in the second direction y as the first semiconductor element 11). By offsetting the first semiconductor element 11 and the second semiconductor element 12 toward the same side in the second direction y, the flowability of molten resin improves during the process of forming the sealing resin 8. Specifically, the molten resin flows more easily from the x2 side toward the x1 side in the first direction x around the first semiconductor element 11 and the second semiconductor element 12. Consequently, adhesion between the sealing resin 8 and each of the first pad portion 21 (the first lead 2) and the second pad portion 31 (the second lead 3) is improved, so that internal delamination of the sealing resin 8 is prevented. Additionally, the semiconductor device A12 provides the same advantages as the semiconductor device A1, to the extent that they share the same configuration.

### Third Variation of First Embodiment

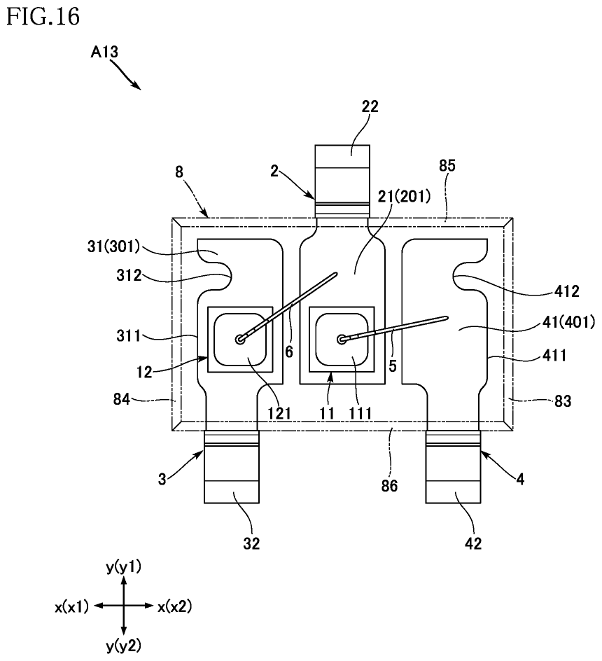

FIG. 16 shows a third variation of the semiconductor device A1. FIG. 16 is a bottom view showing a main portion of the semiconductor device A13 according to the third variation. In FIG. 16, the outline of the sealing resin 8 is indicated by an imaginary line (dash-dot-dot line). In the semiconductor device A13, the shapes of the second pad portion 31 and the third pad portion 41, as well as the positions of the first semiconductor element 11 and the second semiconductor element 12, differ from those in the semiconductor device A1.

In the semiconductor device A13, the recess 312 in the second pad portion 31 is a position in the second pad portion 31 offset toward the y1 side in the second direction y. The recess 412 in the third pad portion 41 is at a position in the third pad portion 41 offset toward the y1 side in the second direction y. Also, the first semiconductor element 11 on the first pad portion 21 is offset toward the y2 side in the second direction y. The second semiconductor element 12 is offset toward the same side in the second direction y as the first semiconductor element 11. In other words, the second semiconductor element 12 on the second pad portion 31 is offset toward the y2 side in the second direction y. As viewed in the first direction x, the second semiconductor element 12 overlaps with the entirety of the first semiconductor element 11.

In the semiconductor device A13, the first semiconductor element 11 and the second semiconductor element 12, which are respectively mounted on the first pad portion 21 and the second pad portion 31 positioned next to each other in the first direction x, overlap with each other as viewed in the first direction x. The first semiconductor element 11 on the first pad portion 21 is offset toward the y2 side in the second direction y (one side in the second direction y). The second semiconductor element 12 on the second pad portion 31 is offset toward the y2 side in the second direction y (the same side in the second direction y as the first semiconductor element 11). By offsetting the first semiconductor element 11 and the second semiconductor element 12 toward the same side in the second direction y, the flowability of molten resin improves during the process of forming the sealing resin 8. Specifically, the molten resin flows more easily from the x2 side toward the x1 side in the first direction x around the first semiconductor element 11 and the second semiconductor element 12. Consequently, adhesion between the sealing resin 8 and each of the first pad portion 21 (the first lead 2) and the second pad portion 31 (the second lead 3) is improved, so that internal delamination of the sealing resin 8 is prevented. Additionally, the semiconductor device A13 provides the same advantages as the semiconductor device A1, to the extent that they share the same configuration.

### Second Embodiment

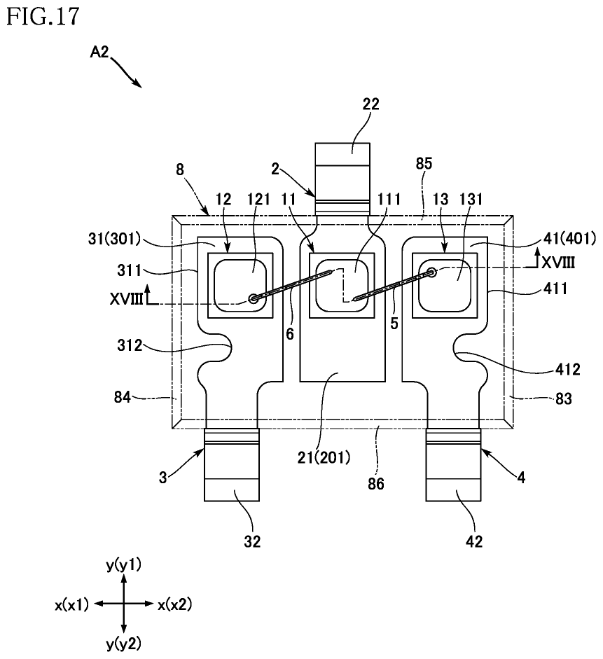

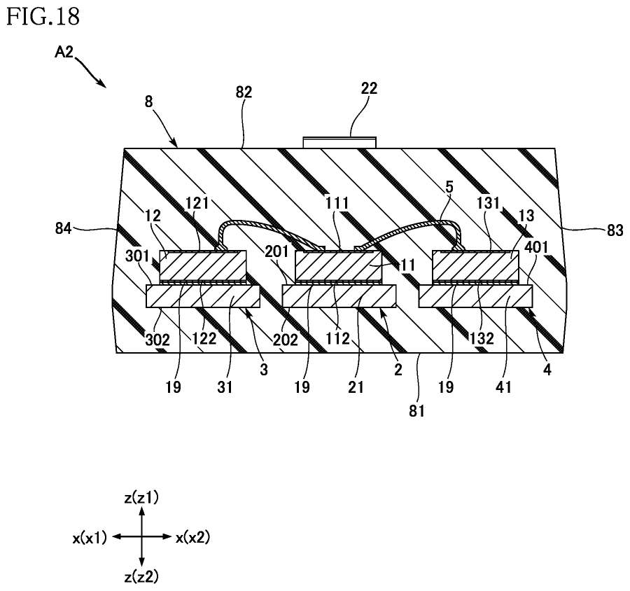

FIGS. 17 and 18 show a semiconductor device according to a second embodiment the present disclosure. FIG. 17 is a bottom view showing a main portion of the semiconductor device A2 according to the present embodiment. FIG. 18 is a sectional view taken along line XVIII-XVIII in FIG. 17. In FIG. 17, the outline of the sealing resin 8 is indicated by an imaginary line (dash-dot-dot line).

The semiconductor device A2 additionally includes a third semiconductor element 13. The third semiconductor element 13 is a diode. As shown in FIGS. 17 and 18, the third semiconductor element 13 includes an obverse-surface electrode 131 and a reverse-surface electrode 132. The obverse-surface electrode 131 is disposed on a surface of the third semiconductor element 13 facing the z1 side in the thickness direction z. The reverse-surface electrode 132 is disposed on a surface of the third semiconductor element 13 facing the z2 side in the thickness direction z. For example, the obverse-surface electrode 131 is an anode, and the reverse-surface electrode 132 is a cathode. In the semiconductor device A2, the obverse-surface electrode 111 of the first semiconductor element 11 is a cathode, and the reverse-surface electrode 112 is an anode. The obverse-surface electrode 121 of the second semiconductor element 12 is an anode, and the reverse-surface electrode 122 is a cathode.

As shown in FIG. 18, the third semiconductor element 13 is bonded to the third obverse surface 401 of the third pad portion 41 via a conductive bonding layer 19. In the present embodiment, the conductive bonding layer 19 is made of a conductive material. The reverse-surface electrode 132 of the third semiconductor element 13 faces the third obverse surface 401. The reverse-surface electrode 132 and the third obverse surface 401 are electrically bonded via the conductive bonding layer 19. The third semiconductor element 13 is die-bonded to the third obverse surface 401 of the third pad portion 41.

As shown in FIG. 17, the third semiconductor element 13 on the third pad portion is offset toward one side in the second direction y. The third semiconductor element 13 is offset toward the same side in the second direction y as the first semiconductor element 11 and the second semiconductor element 12. In the present embodiment, the third semiconductor element 13 on the third pad portion 41 is offset toward the y1 side in the second direction y. Also, the third semiconductor element 13 is spaced apart from the recess 412 in the second direction y.

As viewed in the first direction x, the third semiconductor element 13 overlaps with the first semiconductor element 11 and the second semiconductor element 12. In the illustrated example, the first semiconductor element 11, the second semiconductor element 12, and the third semiconductor element 13 are of the same size. As viewed in the first direction x, the third semiconductor element 13 overlaps with the entirety of the first semiconductor element 11 and the entirety of the second semiconductor element 12.

In the present embodiment, the first bonding wire 5 is bonded to the obverse-surface electrode 111 of the first semiconductor element 11 and to the obverse-surface electrode 131 of the third semiconductor element 13. The second bonding wire 6 is bonded to the obverse-surface electrode 121 of the second semiconductor element 12 and to the obverse-surface electrode 111 of the first semiconductor element 11.

In the present embodiment, the first semiconductor element 11, the second semiconductor element 12, and the third semiconductor element 13, which are respectively mounted on the first pad portion 21, the second pad portion 31, and the third pad portion 41 positioned next to one another in the first direction x, overlap with one another as viewed in the first direction x. The first semiconductor element 11 on the first pad portion 21 is offset toward the y1 side in the second direction y (one side in the second direction y). The second semiconductor element 12 on the second pad portion 31 is offset toward the y1 side in the second direction y (the same side in the second direction y as the first semiconductor element 11). The third semiconductor element 13 on the third pad portion 41 is offset toward the y1 side in the second direction y (the same side in the second direction y as the first semiconductor element 11). By offsetting the first semiconductor element 11, the second semiconductor element 12, and the third semiconductor element 13 toward the same side in the second direction y, the flowability of molten resin improves during the process of forming the sealing resin 8. Specifically, the molten resin flows more easily from the x2 side toward the x1 side in the first direction x around the first semiconductor element 11, the second semiconductor element 12, and the third semiconductor element 13. Consequently, adhesion between the sealing resin 8 and each of the first pad portion 21 (the first lead 2), the second pad portion 31 (the second lead 3), and the third pad portion 41 (the third lead 4) is improved, so that internal delamination of the sealing resin 8 is prevented.

In the semiconductor device A2, the third semiconductor element 13 overlaps with the entirety of the first semiconductor element 11 and the entirety of the second semiconductor element 12 as viewed in the first direction x. With this configuration, the flowability of molten resin is improved during the formation of the sealing resin 8. Specifically, the molten resin flows more easily from the x2 side toward the x1 side in the first direction x around the first semiconductor element 11, the second semiconductor element 12, and the third semiconductor element 13. Consequently, adhesion between the sealing resin 8 and each of the first pad portion 21, the second pad portion 31, and the third pad portion 41 is improved, so that internal delamination of the sealing resin 8 is prevented more reliably.

The second semiconductor element 12 is mounted on the second pad portion 31 that includes a recess 312. The recess 312 is recessed inward from the edge 311, which is an edge of the second pad portion 31 in the first direction x. The third semiconductor element 13 is mounted on the third pad portion 41 that includes a recess 412. The recess 412 is recessed inward from the edge 411, which is an edge of the third pad portion 41 in the first direction x. This serves to improve adhesion between the sealing resin 8 and each of the second pad portion 31 (the second lead 3) and the third pad portion 41 (the third lead 4). This is even more desirable for preventing internal delamination of the sealing resin 8.

### First Variation of Second Embodiment

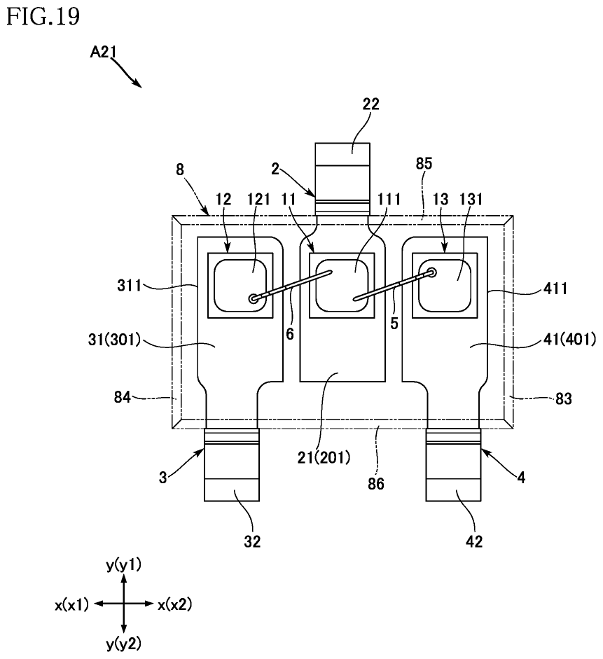

FIG. 19 shows a first variation of the semiconductor device A2. FIG. 19 is a bottom view showing a main portion of the semiconductor device A21 according to the first variation.
In FIG. 19, the outline of the sealing resin 8 is indicated by an imaginary line (dash-dot-dot line). In the semiconductor device A21, the shapes of the second pad portion 31 and the third pad portion 41 differ from those in the semiconductor device A2.

In the semiconductor device A21, the second pad portion 31 does not include a recess 312, and the third pad portion 41 does not include a recess 412. The position of the first semiconductor element 11 on the first pad portion 21, the position of the second semiconductor element 12 on the second pad portion 31, and the position of the third semiconductor element 13 on the third pad portion 41 are the same as those in the semiconductor device A2.

In the semiconductor device A21, the first semiconductor element 11, the second semiconductor element 12, and the third semiconductor element 13, which are respectively mounted on the first pad portion 21, the second pad portion 31, and the third pad portion 41 positioned next to one another in the first direction x, overlap with one another as viewed in the first direction x. The first semiconductor element 11 on the first pad portion 21 is offset toward the y1 side in the second direction y (one side in the second direction y). The second semiconductor element 12 on the second pad portion 31 is offset toward the y1 side in the second direction y (the same side in the second direction y as the first semiconductor element 11). The third semiconductor element 13 on the third pad portion 41 is offset toward the y1 side in the second direction y (the same side in the second direction y as the first semiconductor element 11). By offsetting the first semiconductor element 11, the second semiconductor element 12, and the third semiconductor element 13 toward the same side in the second direction y, the flowability of molten resin improves during the process of forming the sealing resin 8. Specifically, the molten resin flows more easily from the x2 side toward the x1 side in the first direction x around the first semiconductor element 11, the second semiconductor element 12, and the third semiconductor element 13. Consequently, adhesion between the sealing resin 8 and each of the first pad portion 21 (the first lead 2), the second pad portion 31 (the second lead 3), and the third pad portion 41 (the third lead 4) is improved, so that internal delamination of the sealing resin 8 is prevented. Additionally, the semiconductor device A21 provides the same advantages as the semiconductor device A2, to the extent that they share the same configuration.

### Second Variation of Second Embodiment

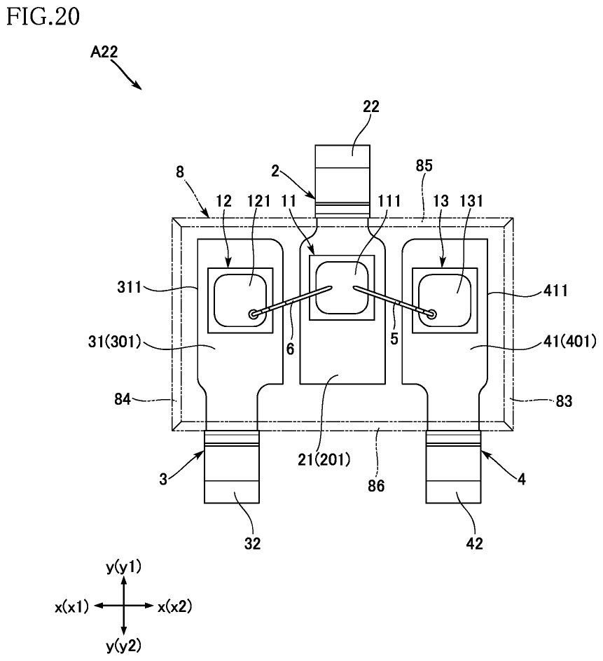

FIG. 20 shows a second variation of the semiconductor device A2. FIG. 20 is a bottom view showing a main portion of the semiconductor device A22 according to the second variation. In FIG. 20, the outline of the sealing resin 8 is indicated by an imaginary line (dash-dot-dot line). In the semiconductor device A22, the position of the second semiconductor element 12 on the second pad portion 31 and the position of the third semiconductor element 13 on the third pad portion 41 differ from those in the semiconductor device A21 described above.

In the semiconductor device A22, the second semiconductor element 12 and the third semiconductor element 13 are positioned closer to the y2 side in the second direction y than in the semiconductor device A21. In this variation, as viewed in the first direction x, the second semiconductor element 12 and the third semiconductor element 13 each overlap with only a portion of the first semiconductor element 11, rather than with the entirety of the first semiconductor element 11. As can be seen in FIG. 20, the second semiconductor element 12 and the third semiconductor element 13 each overlap with most of the first semiconductor element 11 as viewed in the first direction x. In addition, the third semiconductor element 13 overlaps with the entirety of the second semiconductor element 12 as viewed in the first direction x.

In the semiconductor device A22, the first semiconductor element 11, the second semiconductor element 12, and the third semiconductor element 13, which are respectively mounted on the first pad portion 21, the second pad portion 31, and the third pad portion 41 positioned next to one another in the first direction x, overlap with one another as viewed in the first direction x. The first semiconductor element 11 on the first pad portion 21 is offset toward the y1 side in the second direction y (one side in the second direction y). The second semiconductor element 12 on the second pad portion 31 is offset toward the y1 side in the second direction y (the same side in the second direction y as the first semiconductor element 11). The third semiconductor element 13 on the third pad portion 41 is offset toward the y1 side in the second direction y (the same side in the second direction y as the first semiconductor element 11). By offsetting the first semiconductor element 11, the second semiconductor element 12, and the third semiconductor element 13 toward the same side in the second direction y, the flowability of molten resin improves during the process of forming the sealing resin 8. Specifically, the molten resin flows more easily from the x2 side toward the x1 side in the first direction x around the first semiconductor element 11, the second semiconductor element 12, and the third semiconductor element 13. Consequently, adhesion between the sealing resin 8 and each of the first pad portion 21 (the first lead 2), the second pad portion 31 (the second lead 3), and the third pad portion 41 (the third lead 4) is improved, so that internal delamination of the sealing resin 8 is prevented. Additionally, the semiconductor device A22 provides the same advantages as the semiconductor device A2, to the extent that they share the same configuration.

### Third Variation of Second Embodiment

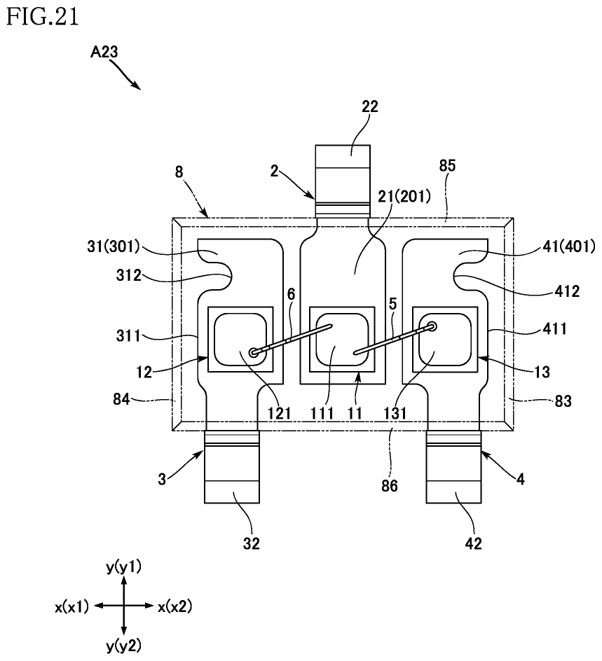

FIG. 21 shows a third variation of the semiconductor device A2. FIG. 21 is a bottom view showing a main portion of the semiconductor device A23 according to the third variation. In FIG. 21, the outline of the sealing resin 8 is indicated by an imaginary line (dash-dot-dot line). In the semiconductor device A23, the shapes of the second pad portion 31 and the third pad portion 41, as well as the positions of the first semiconductor element 11, the second semiconductor element 12, and the third semiconductor element 13 differ from those in the semiconductor device A2.

In the semiconductor device A23, the recess 312 in the second pad portion 31 is at position in the second pad portion 31 offset toward the y1 side in the second direction y. The recess 412 in the third pad portion 41 is at a position in the third pad portion 41 offset toward the y1 side in the second direction y. Also, the first semiconductor element 11 on the first pad portion 21 is offset toward the y2 side in the second direction y. The second semiconductor element 12 is offset toward the same side in the second direction y as the first semiconductor element 11. In other words, in this variation, the second semiconductor element 12 on the second pad portion 31 is offset toward the y2 side in the second direction y. The third semiconductor element 13 is offset toward the same side in the second direction y as the first semiconductor element 11. In other words, the third semiconductor element 13 on the third pad portion 41 is offset toward the y2 side in the second direction y. As viewed in the first direction x, the third semiconductor element 13 overlaps with the entirety of the first semiconductor element 11 and the entirety of the second semiconductor element 12.

In the semiconductor device A23, the first semiconductor element 11, the second semiconductor element 12, and the third semiconductor element 13, which are respectively mounted on the first pad portion 21, the second pad portion 31, and the third pad portion 41 positioned next to one another in the first direction x, overlap with one another as viewed in the first direction x. The first semiconductor element 11 on the first pad portion 21 is offset toward the y2 side in the second direction y (one side in the second direction y). The second semiconductor element 12 on the second pad portion 31 is offset toward the y2 side in the second direction y (the same side in the second direction y as the first semiconductor element 11). The third semiconductor element 13 on the third pad portion 41 is offset toward the y2 side in the second direction y (the same side in the second direction y as the first semiconductor element 11). By offsetting the first semiconductor element 11, the second semiconductor element 12, and the third semiconductor element 13 toward the same side in the second direction y, the flowability of molten resin improves during the process of forming the sealing resin 8. Specifically, the molten resin flows more easily from the x2 side toward the x1 side in the first direction x around the first semiconductor element 11, the second semiconductor element 12, and the third semiconductor element 13. Consequently, adhesion between the sealing resin 8 and each of the first pad portion 21 (the first lead 2), the second pad portion 31 (the second lead 3), and the third pad portion 41 (the third lead 4) is improved, so that internal delamination of the sealing resin 8 is prevented. Additionally, the semiconductor device A23 provides the same advantages as the semiconductor device A2, to the extent that they share the same configuration.

The semiconductor device according to the present disclosure is not limited to the embodiments described above. Various modifications in design may be made freely in the specific structure of each part of the semiconductor device according to the present disclosure.

The present disclosure includes configurations of the clauses below.

### Clause 1.

A semiconductor device comprising:
a first lead including a first pad portion;
a first semiconductor element disposed on a first side in a thickness direction relative to the first pad portion;
a second lead including a second pad portion spaced apart from the first pad portion toward a first side in a first direction perpendicular to the thickness direction;
a second semiconductor element disposed on the first side in the thickness direction relative to the second pad portion;
a first bonding wire bonded to the first semiconductor element;
a second bonding wire bonded to the second semiconductor element; and
a sealing resin covering the first semiconductor element, the second semiconductor element, the first pad portion, the second pad portion, the first bonding wire, and the second bonding wire,
wherein as viewed in the first direction, the first semiconductor element and the second semiconductor element overlap with each other,
the first semiconductor element on the first pad portion is offset toward one side in a second direction perpendicular to the thickness direction and the first direction, and
the second semiconductor element on the second pad portion is offset toward the one side in the second direction.

### Clause 2.

The semiconductor device according to Clause 1, wherein a length in the second direction of an overlap between the first semiconductor element and the second semiconductor element as viewed in the first direction is at least 60% of a length of the first semiconductor element in the second direction.

### Clause 3.

The semiconductor device according to Clause 1, wherein as viewed in the first direction, the second semiconductor element overlaps with an entirety of the first semiconductor element.

### Clause 4.

The semiconductor device according to any one of Clauses 1 to 3, wherein the second bonding wire is electrically bonded to the second semiconductor element and to the first pad portion.

### Clause 5.

The semiconductor device according to any one of Clauses 1 to 4, wherein the second pad portion includes a recess that is recessed inward from an edge of the second pad portion in the first direction, and
the second semiconductor element is spaced apart from the recess in the second direction.

### Clause 6.

The semiconductor device according to any one of Clauses 1 to 5, further comprising a third lead including a third pad portion spaced apart from the first pad portion toward a second side in the first direction.

### Clause 7.

The semiconductor device according to Clause 6, wherein the first bonding wire is electrically bonded to the first semiconductor element and to the third pad portion.

### Clause 8.

The semiconductor device according to Clause 7, wherein each of the first semiconductor element and the second semiconductor element comprises a diode.

### Clause 9.

The semiconductor device according to Clause 6, further comprising a third semiconductor element disposed on the first side in the thickness direction relative to the third pad portion;
wherein as viewed in the first direction, the third semiconductor element overlaps with the first semiconductor element and the second semiconductor element.

### Clause 10.

The semiconductor device according to Clause 9, wherein as viewed in the first direction, the third semiconductor element overlaps with an entirety of the first semiconductor element and an entirety of the second semiconductor element.

### Clause 11.

The semiconductor device according to Clause 9 or 10, wherein the first bonding wire is electrically bonded to the first semiconductor element and to the third semiconductor element, and
the second bonding wire is electrically bonded to the second semiconductor element and to the first semiconductor element.

### Clause 12.

The semiconductor device according to any one of Clauses 6 to 11, wherein the first lead includes a first terminal portion connected to the first pad portion on a first side in the second direction, at least a portion of the first terminal portion being exposed from the sealing resin,
the second lead includes a second terminal portion connected to the second pad portion on a second side in the second direction, at least a portion of the second terminal portion being exposed from the sealing resin, and
the third lead includes a third terminal portion connected to the third pad portion on the second side in the second direction, at least a portion of the third terminal portion being exposed from the sealing resin.

### Clause 13.

The semiconductor device according to Clause 12, wherein the first semiconductor element on the first pad portion is offset toward the first side in the second direction, and
the second semiconductor element on the second pad portion is offset toward the first side in the second direction.

### Clause 14.

The semiconductor device according to any one of Clauses 1 to 13, wherein the sealing resin includes a first resin side surface facing a second side in the first direction, and
the first resin side surface includes a resin injection mark having a rougher surface than another region of the first resin side surface.

### Clause 15.

The semiconductor device according to Clause 14, wherein the resin injection mark is elongated in the second direction.

1. A semiconductor device comprising:
a first lead including a first pad portion;
a first semiconductor element disposed on a first side in a thickness direction relative to the first pad portion;
a second lead including a second pad portion spaced apart from the first pad portion toward a first side in a first direction perpendicular to the thickness direction;
a second semiconductor element disposed on the first side in the thickness direction relative to the second pad portion;
a first bonding wire bonded to the first semiconductor element;
a second bonding wire bonded to the second semiconductor element; and
a sealing resin covering the first semiconductor element, the second semiconductor element, the first pad portion, the second pad portion, the first bonding wire, and the second bonding wire,
wherein as viewed in the first direction, the first semiconductor element and the second semiconductor element overlap with each other,
the first semiconductor element on the first pad portion is offset toward one side in a second direction perpendicular to the thickness direction and the first direction, and
the second semiconductor element on the second pad portion is offset toward the one side in the second direction.

2. The semiconductor device according to claim 1, wherein a length in the second direction of an overlap between the first semiconductor element and the second semiconductor element as viewed in the first direction is at least 60% of a length of the first semiconductor element in the second direction.

3. The semiconductor device according to claim 1, wherein as viewed in the first direction, the second semiconductor element overlaps with an entirety of the first semiconductor element.

4. The semiconductor device according to claim 1, wherein the second bonding wire is electrically bonded to the second semiconductor element and to the first pad portion.

5. The semiconductor device according to claim 1, wherein the second pad portion includes a recess that is recessed inward from an edge of the second pad portion in the first direction, and
the second semiconductor element is spaced apart from the recess in the second direction.

6. The semiconductor device according to claim 1, further comprising a third lead including a third pad portion spaced apart from the first pad portion toward a second side in the first direction.

7. The semiconductor device according to claim 6, wherein the first bonding wire is electrically bonded to the first semiconductor element and to the third pad portion.

8. The semiconductor device according to claim 7, wherein each of the first semiconductor element and the second semiconductor element comprises a diode.

9. The semiconductor device according to claim 6, further comprising a third semiconductor element disposed on the first side in the thickness direction relative to the third pad portion;
wherein as viewed in the first direction, the third semiconductor element overlaps with the first semiconductor element and the second semiconductor element.

10. The semiconductor device according to claim 9, wherein as viewed in the first direction, the third semiconductor element overlaps with an entirety of the first semiconductor element and an entirety of the second semiconductor element.

11. The semiconductor device according to claim 9, wherein the first bonding wire is electrically bonded to the first semiconductor element and to the third semiconductor element, and
the second bonding wire is electrically bonded to the second semiconductor element and to the first semiconductor element.

12. The semiconductor device according to claim 6, wherein the first lead includes a first terminal portion connected to the first pad portion on a first side in the second direction, at least a portion of the first terminal portion being exposed from the sealing resin,
the second lead includes a second terminal portion connected to the second pad portion on a second side in the second direction, at least a portion of the second terminal portion being exposed from the sealing resin, and
the third lead includes a third terminal portion connected to the third pad portion on th second side in the second direction, at least a portion of the third terminal portion being exposed from the sealing resin.

13. The semiconductor device according to claim 12, wherein the first semiconductor element on the first pad portion is offset toward the first side in the second direction, and
the second semiconductor element on the second pad portion is offset toward the first side in the second direction.

14. The semiconductor device according to claim 1, wherein the sealing resin includes a first resin side surface facing a second side in the first direction, and
the first resin side surface includes a resin injection mark having a rougher surface than another region of the first resin side surface.

15. The semiconductor device according to claim 14, wherein the resin injection mark is elongated in the second direction.
